(19) United States
(12) Patent Application Publication
(10) Pub. No.: US 2026/0213485 A1
(43) Pub. Date: Jul. 23, 2026

(54) LASER DEVICE AND ELECTRONIC DEVICE MANUFACTURING METHOD

(71) Applicant: Gigaphoton Inc., Tochigi (JP)

(72) Inventors: Shunya OIWA, Tochigi (JP); Hirotaka MIYAMOTO, Tochigi (JP)

(73) Assignee: Gigaphoton Inc., Tochigi (JP)

(21) Appl. No.: 19/406,467

(22) Filed: Dec. 2, 2025

(30) Foreign Application Priority Data
Jan. 20, 2025 (JP) 2025-007635

(51) Int. Cl. H01S 3/00; H01S 3/034

(52) U.S. Cl. CPC H01S 3/0057; H01S 3/034

(57) ABSTRACT

A laser device includes a discharge-excitation-type laser oscillator configured to output pulse laser light in an ultraviolet wavelength range, a first optical pulse stretcher including a beam splitter and a plurality of concave mirrors and configured to extend a pulse width of the pulse laser light, and a relay lens including a first lens and a second lens arranged on an optical path of the pulse laser light with the pulse width extended. The first lens is a spherical plano-convex lens, and the second lens has a focal length in a longitudinal direction of a beam cross section of the pulse laser light shorter than a focal length in a transverse direction thereof.

### CROSS-REFERENCE TO RELATED APPLICATIONS

The present application claims the benefit of Japanese Patent Application No. 2025-007635, filed on Jan. 20, 2025, the entire contents of which are hereby incorporated by reference.

### BACKGROUND

### 1. Technical Field

The present disclosure relates to a laser device and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. In the following, a gas laser device with a narrowed spectral line width is referred to as a line narrowing gas laser device.

### LIST OF DOCUMENTS

### Patent Documents

Patent Document 1: US Patent Application Publication No. 2016/0248219
Patent Document 2: Japanese Patent Application Publication No. 2005-167082

### SUMMARY

A laser device according to an aspect of the present disclosure includes a discharge-excitation-type laser oscillator configured to output pulse laser light in an ultraviolet wavelength range, a first optical pulse stretcher including a beam splitter and a plurality of concave mirrors and configured to extend a pulse width of the pulse laser light, and a relay lens including a first lens and a second lens arranged on an optical path of the pulse laser light with the pulse width extended. Here, the first lens is a spherical plano-convex lens, and the second lens has a focal length in a longitudinal direction of a beam cross section of the pulse laser light shorter than a focal length in a transverse direction thereof.

An electronic device manufacturing method according to an aspect of the present disclosure includes outputting pulse laser light from a laser device to an exposure apparatus, and exposing a photosensitive substrate to the pulse laser light in the exposure apparatus to manufacture an electronic device. Here, the laser device includes a discharge-excitation-type laser oscillator configured to output the pulse laser light in an ultraviolet wavelength range, a first optical pulse stretcher including a beam splitter and a plurality of concave mirrors and configured to extend a pulse width of the pulse laser light, and a relay lens including a first lens and a second lens arranged on an optical path of the pulse laser light with the pulse width extended. The first lens is a spherical plano-convex lens, and the second lens has a focal length in a longitudinal direction of a beam cross section of the pulse laser light shorter than a focal length in a transverse direction thereof.

### BRIEF DESCRIPTION OF THE DRAWINGS

Embodiments of the present disclosure will be described below merely as examples with reference to the accompanying drawings.

FIG. 1 is a view for explaining a beam divergence angle.

FIG. 2 is a view showing an example of a beam cross-sectional shape of pulse laser light.

FIG. 3 is a view for explaining a relay lens.

FIG. 4 is a view showing the internal configuration of a laser device according to a comparative example as viewed from the front.

FIG. 5 is a view showing the internal configuration of the laser device according to the comparative example as viewed from above.

FIG. 6 is a view showing the internal configuration of the laser device according to a first embodiment as viewed from the front.

FIG. 7 is a view showing the internal configuration of the laser device according to the first embodiment as viewed from above.

FIG. 8 is a view showing the configuration of a first lens.

FIG. 9 is a view showing the configuration of a second lens.

FIG. 10 is a view showing focal lengths of the second lens in a first direction and a second direction.

FIG. 11 is a view showing a focal length of a convex cylindrical surface.

FIG. 12 is a view for explaining a change in the beam divergence angle in the first direction.

FIG. 13 is a view of an optical path length changing mechanism viewed from an optical axis direction.

FIG. 14 is a view of the optical path length changing mechanism viewed from the first direction.

FIG. 15 is a view showing the second lens according to a second embodiment.

FIG. 16 is a view showing a focal length due to a first curvature of the second lens and a focal length due to a second curvature thereof.

FIG. 17 is a diagram schematically showing a configuration example of an exposure apparatus.

### DESCRIPTION OF EMBODIMENTS

### Contents

1. Description of terms
1.1 Beam divergence angle
1.2 Relay lens
2. Comparative example
2.1 Configuration
2.2 Operation
2.3 Problem
3. First embodiment
3.1 Configuration
3.2 Operation
3.3 Effect
4. Second embodiment
4.1 Configuration
4.2 Operation
4.3 Effect
5. Modification
6. Electronic device manufacturing method

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Terms

### 1.1 Beam Divergence Angle

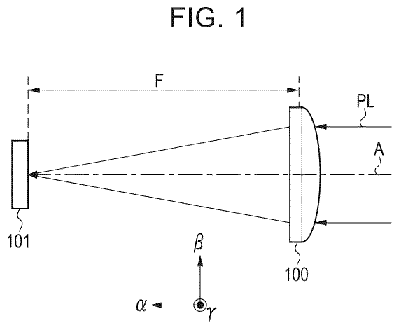

FIG. 1 explains a beam divergence angle. When pulse laser light PL is concentrated by a light concentrating lens 100 as shown in FIG. 1, a value obtained by dividing a size of a light concentrating spot formed at a position of a focal length F of the light concentrating lens 100 by the focal length F is defined as a “beam divergence angle”. Here, the size of the light concentrating spot is a diameter or a full width of the light concentrating spot, and can be measured using a two-dimensional image sensor 101 or the like.

In the present disclosure, a reference sign A represents an optical axis of an optical system, and the pulse laser light PL travels along the optical axis A. A direction parallel to the optical axis A is referred to as an optical axis direction α. Further, a direction orthogonal to the optical axis direction α is defined as a first direction β, and a direction orthogonal to the optical axis direction α and the first direction β is defined as a second direction γ.

The two-dimensional image sensor 101 has a light receiving surface parallel to the first direction β and the second direction γ. That is, the beam divergence angle in the first direction β and the beam divergence angle in the second direction γ can be measured by measuring the size of the light concentrating spot in the first direction β and the size thereof in the second direction γ, respectively.

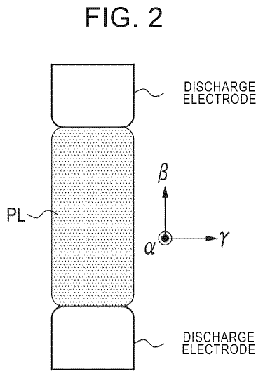

FIG. 2 shows an example of a beam cross-sectional shape of the pulse laser light PL. As shown in FIG. 2, the beam cross section of the pulse laser light PL output from a discharge-excitation-type laser device forms a rectangle in which the longitudinal direction is a discharge direction in which a pair of discharge electrodes face each other, and the transverse direction is a direction perpendicular to the discharge direction. In the present disclosure, the longitudinal direction of the beam cross section is defined as the first direction β, and the transverse direction of the beam cross section is defined as the second direction γ.

Thus, in the discharge-excitation-type laser device, since the cross-sectional shape of the pulse laser light PL is a rectangle, the beam divergence angles differ between the first direction β and the second direction γ, and normally, the beam divergence angle in the first direction β is larger than the beam divergence angle in the second direction γ.

### 1.2 Relay Lens

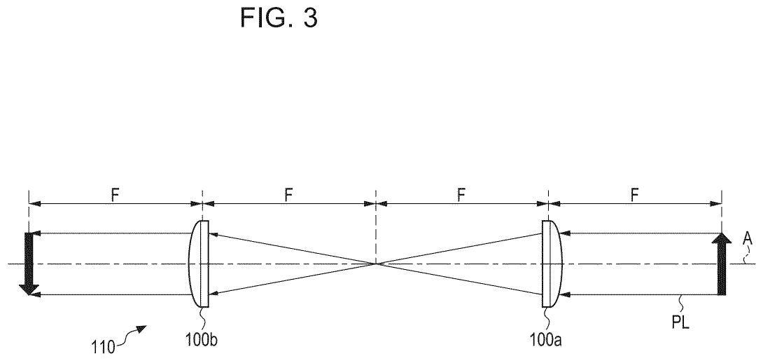

FIG. 3 explains a relay lens. As shown in FIG. 3, a relay lens 110 includes an upstream-side lens 100a and a downstream-side lens 100b arranged along the optical axis A. In the example shown in FIG. 3, the upstream-side lens 100a and the downstream-side lens 100b are spherical plano-convex lenses, and are arranged such that their respective flat surfaces face each other. Further, focal lengths of the upstream-side lens 100a and the downstream-side lens 100b are the same. The focal length is represented by F.

Ideally, the upstream-side lens 100a and the downstream-side lens 100b are arranged such that a rear focal position of the upstream-side lens 100a coincides with a front focal position of the downstream-side lens 100b. That is, the upstream-side lens 100a and the downstream-side lens 100b are arranged such that an optical path distance is 2F. The beam cross-sectional shape of the pulse laser light PL at the front focal position of the upstream-side lens 100a is inverted and imaged at a ratio of 1:1 at the rear focal position of the downstream-side lens 100b.

### 2. Comparative Example

The comparative example of the present disclosure is an example recognized by the applicant as known only by the applicant, and is not a publicly known example admitted by the applicant.

### 2.1 Configuration

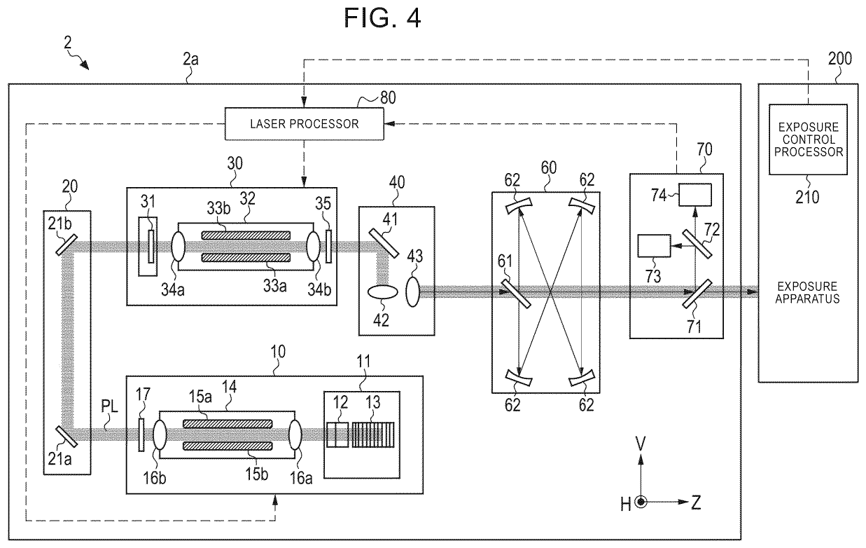

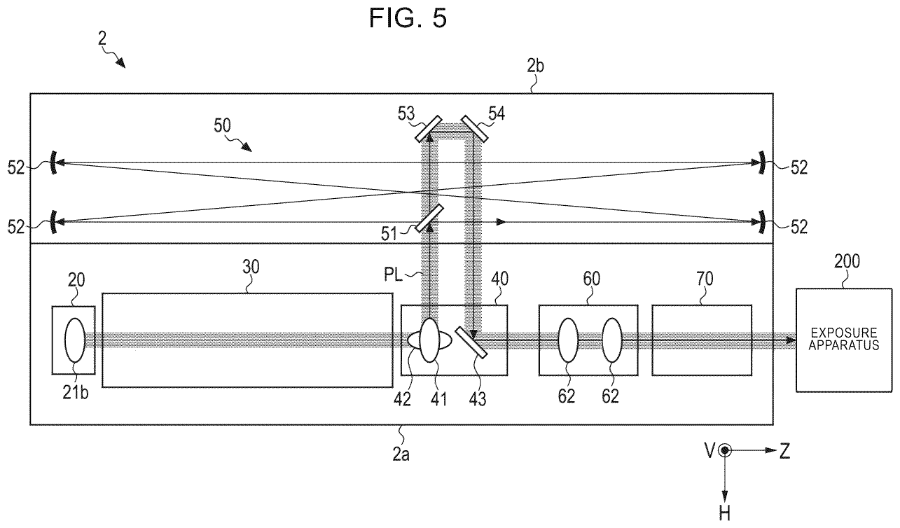

FIGS. 4 and 5 schematically show a configuration example of a laser device 2 according to a comparative example. FIG. 4 shows the internal configuration of the laser device 2 as viewed from the front. FIG. 5 shows the internal configuration of the laser device 2 as viewed from above.

In FIGS. 4 and 5, the height direction of the laser device 2 is defined as a V-axis direction, the length direction thereof is defined as a Z-axis direction, and the depth direction thereof is defined as an H-axis direction. For example, the V-axis direction is parallel to the gravity direction. Further, the Z-axis direction is parallel to an output direction of the pulse laser light PL output from the laser device 2.

The laser device 2 is a discharge-excitation-type line narrowing gas laser device including a master oscillator (MO) 10, an MO beam steering unit 20, a power oscillator (PO) 30, a PO beam steering unit 40, first and second optical pulse stretchers (OPS) 50, 60, a monitor module 70, and a laser processor 80. The master oscillator 10 is an example of the “laser oscillator” according to the technology of the present disclosure.

The master oscillator 10, the MO beam steering unit 20, the power oscillator 30, the PO beam steering unit 40, the second OPS 60, the monitor module 70, and the laser processor 80 are accommodated in a housing 2a. The first OPS 50 is accommodated in a housing 2b. For example, the housing 2b is arranged on a rear side of the housing 2a.

The master oscillator 10 includes a line narrowing module (LNM) 11, a chamber 14, and an output coupling mirror (Output Coupler: OC) 17.

The LNM 11 includes a prism beam expander 12 and a grating 13 for narrowing the spectral line width. The prism beam expander 12 and the grating 13 are arranged in the Littrow arrangement so that an incident angle and a diffraction angle coincide with each other.

The output coupling mirror 17 is a reflection mirror having a reflectance in the range of 40% to 60%. The output coupling mirror 17 and the LNM 11 are arranged to configure an optical resonator.

The chamber 14 is arranged on the optical path of the optical resonator. The chamber 14 includes a pair of discharge electrodes 15a, 15b and two windows 16a, 16b through which the pulse laser light PL passes. The chamber 14 contains an excimer laser gas. The excimer laser gas may include, for example, an Ar gas or a Kr gas as a rare gas, an F₂ gas as a halogen gas, and an Ne gas as a buffer gas.

The MO beam steering unit 20 includes a high reflection mirror 21a and a high reflection mirror 21b. The high reflection mirror 21a and the high reflection mirror 21b are arranged such that the pulse laser light output from the master oscillator 10 enters the power oscillator 30. The high reflection mirror of the present disclosure is a planar mirror with a high reflection film formed on a surface of a substrate formed of, for example, synthetic quartz or calcium fluoride (CaF₂). The high reflection film is a dielectric multilayer film, for example, a film containing fluoride.

The power oscillator 30 includes a rear mirror 31, a chamber 32, and an output coupling mirror 35. The rear mirror 31 and the output coupling mirror 35 are arranged to configure an optical resonator. The power oscillator 30 is an example of the “amplifier” according to the technology of the present disclosure.

The chamber 32 is arranged on the optical path of the optical resonator. The chamber 32 may have a configuration similar to that of the chamber 14 of the master oscillator 10. That is, the chamber 32 includes a pair of discharge electrodes 33a, 33b and two windows 34a, 34b through which the pulse laser light PL passes. The chamber 32 contains the excimer laser gas.

The rear mirror 31 is a reflection mirror having a reflectance in the range of 50% to 90%. The output coupling mirror 35 is a reflection mirror having a reflectance in the range of 10% to 30%.

The PO beam steering unit 40 includes high reflection mirrors 41 to 43 for exchange of light with the first OPS 50. The high reflection mirror 41 is arranged such that the pulse laser light PL output from the power oscillator 30 is reflected to be incident on the high reflection mirror 42. The high reflection mirror 42 is arranged such that the pulse laser light PL reflected by the high reflection mirror 41 is reflected to enter the first OPS 50. The high reflection mirror 43 is arranged such that the pulse laser light PL output from the first OPS 50 is reflected to enter the second OPS 60.

The first OPS 50 includes a beam splitter 51 and a plurality of concave mirrors 52. The beam splitter 51 is arranged on the optical path of the pulse laser light PL reflected by the high reflection mirror 42. The beam splitter 51 is a partial reflection mirror that transmits a part of the incident pulse laser light PL and reflects the other part thereof. The reflectance of the beam splitter 51 is preferably in the range of 40% to 70%, and more preferably about 60%.

The plurality of concave mirrors 52 configure a loop optical path through which a part of the pulse laser light PL reflected by the beam splitter 51 is circulated and returned to the beam splitter 51. A part of the pulse laser light PL having entered from the high reflection mirror 42 and transmitted through the beam splitter 51 is superimposed on a part of the pulse laser light PL having circulated through the loop optical path at least once and reflected by the beam splitter 51. As a result, the pulse width of the pulse laser light PL is extended. In the present disclosure, the pulse width refers to the temporal width of a pulse.

Further, high reflection mirrors 53, 54 arranged such that the pulse laser light PL whose pulse width is extended by the first OPS 50 is reflected to be incident on the high reflection mirror 43 are provided in the housing 2b.

An optical path length of the loop optical path formed by the plurality of concave mirrors 52 is preferably in the range of 30 m to 75 m both inclusive. The number of the plurality of concave mirrors 52 is preferably in the range of 16 to 34 both inclusive.

The second OPS 60 includes a beam splitter 61 and a plurality of concave mirrors 62. The beam splitter 61 is arranged on the optical path of the pulse laser light PL reflected by the high reflection mirror 43. The beam splitter 61 is a partial reflection mirror that transmits a part of the incident pulse laser light PL and reflects the other part thereof. The reflectance of the beam splitter 61 is preferably in the range of 40% to 70%, and more preferably about 60%.

The plurality of concave mirrors 62 configure a loop optical path through which a part of the pulse laser light PL reflected by the beam splitter 61 is circulated and returned to the beam splitter 61. A part of the pulse laser light PL having entered from the high reflection mirror 43 and transmitted through the beam splitter 61 is superimposed on a part of the pulse laser light PL having circulated through the loop optical path at least once and reflected by the beam splitter 61. As a result, the pulse width of the pulse laser light PL is extended.

An optical path length of the loop optical path formed by the plurality of concave mirrors 62 is preferably in the range of 5 m to 25 m both inclusive. The number of the plurality of concave mirrors 62 is preferably in the range of 4 to 12 both inclusive. Therefore, the optical path length of the first OPS 50 is longer than the optical path length of the second OPS 60.

The monitor module 70 includes beam splitters 71, 72, an energy detector 73, and a spectrum detector 74. The beam splitter 71 is arranged on the optical path of the pulse laser light PL output from the second OPS 60. The beam splitter 71 is a partial reflection mirror that transmits a part of the incident pulse laser light PL and reflects the other part thereof.

The beam splitter 72 is arranged on the optical path of the pulse laser light PL reflected by the beam splitter 71. The beam splitter 72 is a partial reflection mirror that transmits a part of the incident pulse laser light PL and reflects the other part thereof.

The energy detector 73 is arranged on the optical path of the pulse laser light PL reflected by the beam splitter 72, and detects the pulse energy of the pulse laser light PL. The spectrum detector 74 is arranged on the optical path of the pulse laser light PL transmitted through the beam splitter 72, and detects the spectral line width and the wavelength of the pulse laser light PL.

An exposure apparatus 200 as an external apparatus is connected to the laser device 2, and the pulse laser light PL transmitted through the beam splitter 71 enters the exposure apparatus 200. The exposure apparatus 200 is provided with an exposure control processor 210. The exposure control processor 210 is connected to the laser processor 80.

The laser processor 80 is connected to the exposure control processor 210, the master oscillator 10, the power oscillator 30, and the monitor module 70.

### 2.2 Operation

Next, operation of the laser device 2 according to the comparative example will be described. First, the laser processor 80 receives data including a target pulse energy, a target wavelength, and a target spectral line width from the exposure control processor 210. When the laser processor 80 receives a light emission trigger from the exposure control processor 210, high voltage pulses from a power source (not shown) are applied between the discharge electrodes 15a, 15b of the master oscillator 10.

When discharge occurs between the discharge electrodes 15a, 15b, the laser gas is excited and undergoes laser oscillation by the optical resonator configured of the output coupling mirror 17 and the LNM 11. As a result, the line-narrowed pulse laser light PL is output from the output coupling mirror 17. The pulse laser light PL is incident on the rear mirror 31 of the power oscillator 30 as seed light by the MO beam steering unit 20.

At the timing when the seed light having transmitted through the rear mirror 31 enters, high voltage pulses from a power source (not shown) are applied between the discharge electrodes 33a, 33b. When discharge occurs between the discharge electrodes 33a, 33b, the laser gas is excited, the seed light is amplified by the Fabry-Perot optical resonator configured of the output coupling mirror 35 and the rear mirror 31, and the amplified pulse laser light PL is output from the output coupling mirror 35. The pulse laser light PL is ultraviolet light having a wavelength in an ultraviolet wavelength range between 150 nm and 380 nm.

The pulse laser light PL output from the output coupling mirror 35 enters the PO beam steering unit 40, and enters the first OPS 50 with the travel direction thereof changed.

The pulse laser light PL having entered the first OPS 50 is extended in the pulse width and returns to the PO beam steering unit 40, and enters the second OPS 60 with the travel direction thereof changed.

The pulse width of the pulse laser light PL having entered the second OPS 60 is further extended, and the pulse laser light PL is output. The pulse laser light PL output from the second OPS 60 enters the monitor module 70. A part thereof is reflected by the beam splitter 71, and the other part thereof is output from the laser device 2 and enters the exposure apparatus 200.

In the monitor module 70, the pulse energy is detected by the energy detector 73, and the spectral line width and the wavelength are detected by the spectrum detector 74.

The laser processor 80 controls the high voltage pulses to be applied between the discharge electrodes 33a, 33b based on the detection result of the pulse energy so that the pulse energy of the pulse laser light PL output from the laser device 2 becomes the target pulse energy.

Further, the laser processor 80 controls a rotation stage (not shown) of the prism beam expander 12 in the LNM 11 based on the detection result of the wavelength so that the wavelength of the pulse laser light PL output from the laser device 2 becomes the target wavelength.

Further, the laser processor 80 controls a wavefront adjuster (not shown) based on the detection result of the spectral line width so that the spectral line width of the pulse laser light PL output from the laser device 2 becomes the target spectral line width.

The pulse width of the pulse laser light PL is extended by the first OPS 50 and the second OPS 60, thereby reducing the coherence. This suppresses occurrence of speckle. Speckle is light and dark spots caused by interference when pulse laser light is scattered in a random medium.

### 2.3 Problem

Next, a problem of the laser device 2 according to the comparative example will be described. In the laser device 2 according to the comparative example, since the devices for extending the optical path length such as the first OPS 50 and the second OPS 60 are arranged, vignetting or the like occurs in the exposure apparatus 200 due to spread of the beam of the pulse laser light PL, and energy loss occurs. Here, vignetting refers to a phenomenon in which a part of a beam is blocked by an optical system.

As a method of suppressing the energy loss, it is conceivable to reduce the beam divergence angle by arranging the relay lens 110 as shown in FIG. 3 on the optical path of the pulse laser light PL and adjusting an inter-lens distance, which is the distance between the upstream-side lens 100a and the downstream-side lens 100b. For example, the relay lens 110 is arranged on the optical path of the pulse laser light PL between the first OPS 50 and the second OPS 60.

However, as shown in FIG. 2, the beam divergence angle differs between the first direction β, which is the longitudinal direction of the beam cross section, and the second direction γ, which is the transverse direction thereof. That is, the inter-lens distance that minimizes the beam divergence angle in the first direction β is different from the inter-lens distance that minimizes the beam divergence angle in the second direction γ. Therefore, in the laser device 2 according to the comparative example, the beam divergence angles in both the longitudinal direction and the transverse direction of the beam cross section cannot be made small together.

The present disclosure provides a discharge-excitation-type laser device capable of reducing a beam divergence angle in each of the longitudinal direction and the transverse direction of the beam cross section.

### 3. First Embodiment

The laser device 2 according to a first embodiment of the present disclosure will be described. Any component same as that described above is denoted by an identical reference sign, and duplicate description thereof is omitted unless specific description is needed.

### 3.1 Configuration

The laser device 2 according to the present embodiment has a similar configuration to the laser device 2 according to the comparative example except that a relay lens is added.

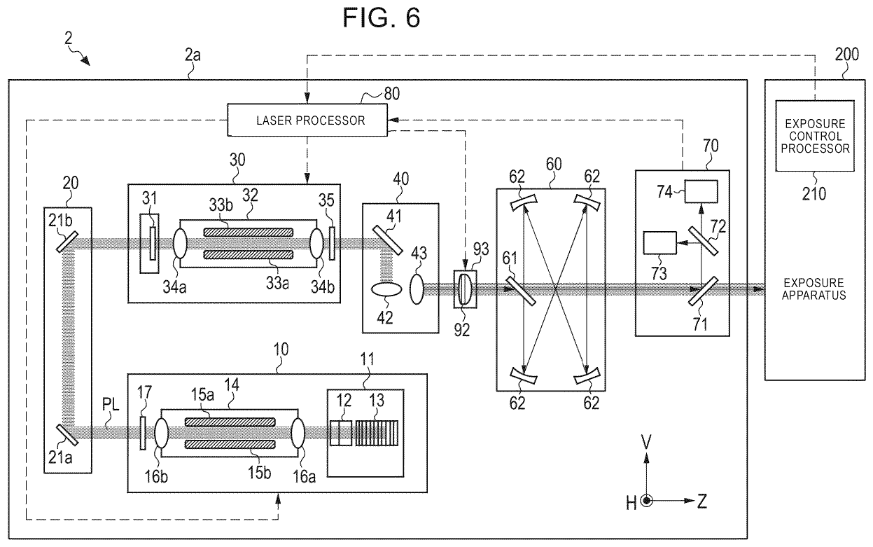

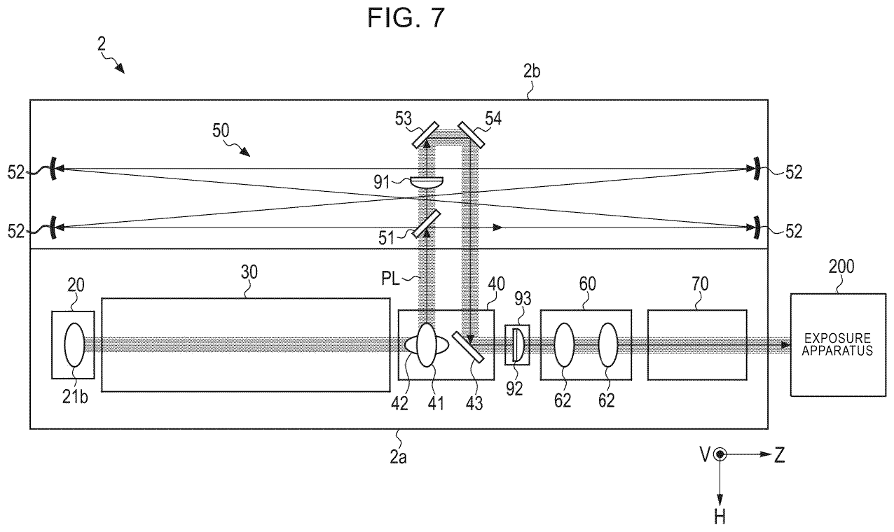

FIGS. 6 and 7 schematically show a configuration example of the laser device 2 according to the first embodiment. FIG. 6 shows the internal configuration of the laser device 2 as viewed from the front. FIG. 7 shows the internal configuration of the laser device 2 as viewed from above.

The relay lens according to the present embodiment includes a first lens 91 and a second lens 92. The second lens 92 is arranged on the optical path of the pulse laser light PL downstream of the first lens 91.

In the present embodiment, the first lens 91 and the second lens 92 are arranged on the optical path of the pulse laser light PL between the first OPS 50 and the second OPS 60. Specifically, the first lens 91 is arranged in the housing 2b, and the second lens 92 is arranged in the housing 2a. For example, the first lens 91 is arranged between the beam splitter 51 and the high reflection mirror 53. The second lens 92 is arranged between the high reflection mirror 43 and the beam splitter 61. That is, the second lens 92 is arranged outside the housing 2b of the first OPS 50 and upstream of the second OPS 60.

The second lens 92 is held by an optical path length changing mechanism 93 so as to be movable along the optical path of the pulse laser light PL. The optical path length changing mechanism 93 is connected to the laser processor 80.

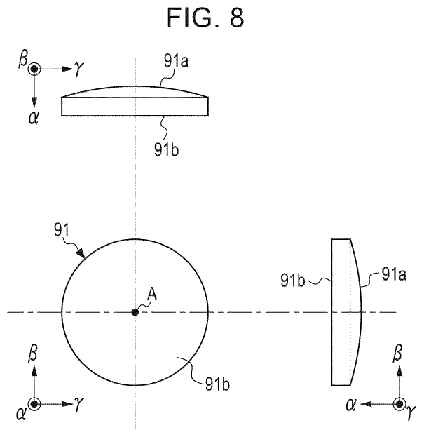

FIG. 8 shows the configuration of the first lens 91. The first lens 91 has a convex spherical surface 91a and a flat surface 91b opposed to each other. That is, the first lens 91 is a spherical planoconvex lens. The first lens 91 is arranged such that the flat surface 91b is perpendicular to the optical axis direction α. At the position where the first lens 91 is arranged, the optical axis direction α corresponds to the H-axis direction, the first direction β corresponds to the V-axis direction, and the second direction γ corresponds to the Z-axis direction.

The focal length of the first lens 91 is determined by the optical characteristic of the convex spherical surface 91a. Since the convex spherical surface 91a has the same optical power in the first direction β and the second direction γ, the first lens 91 has the same focal length in the first direction β and the second direction γ.

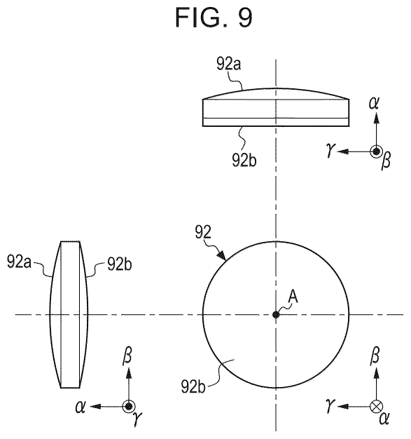

FIG. 9 shows the configuration of the second lens 92. The second lens 92 has a convex spherical surface 92a and a convex cylindrical surface 92b opposed to each other. It is preferable that the convex spherical surface 92a has a focal length equal to the focal length of the convex spherical surface 91a. The convex cylindrical surface 92b is a part of a cylindrical surface whose center axis is parallel to the second direction γ. At the position where the second lens 92 is arranged, the optical axis direction α corresponds to the Z-axis direction, the first direction β corresponds to the V-axis direction, and the second direction γ corresponds to the H-axis direction.

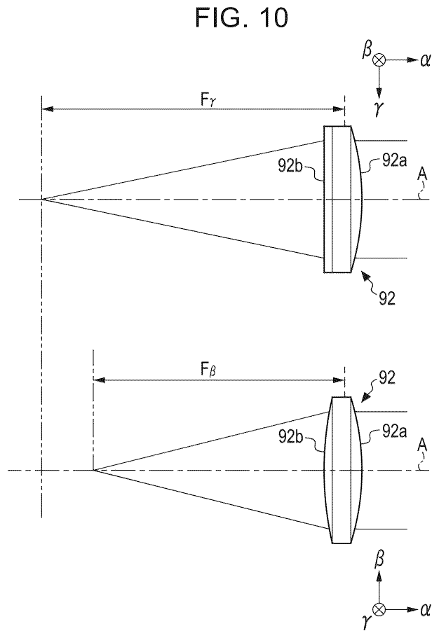

The focal length of the second lens 92 is determined by the optical characteristic of the convex spherical surface 92a and the optical characteristic of the convex cylindrical surface 92b. The convex spherical surface 92a has the same optical power in the first direction β and the second direction γ. The convex cylindrical surface 92b has an optical power only in the first direction β, and concentrates the pulse laser light PL in the first direction β. Therefore, as shown in FIG. 10, the second lens 92 has a focal length F_{β} in the first direction β shorter than a focal length F_{γ} in the second direction γ. Here, it is preferable that the focal length of the convex spherical surface 92a is the same as the focal length of the convex spherical surface 91a of the first lens 91, and is in the range of 500 mm to 1000 mm both inclusive.

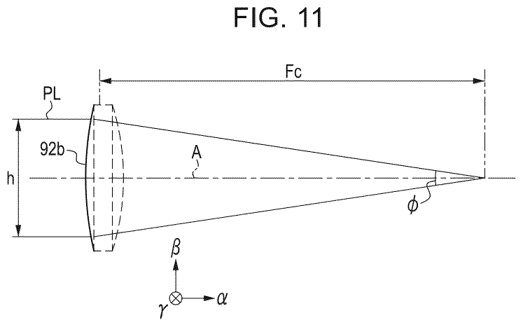

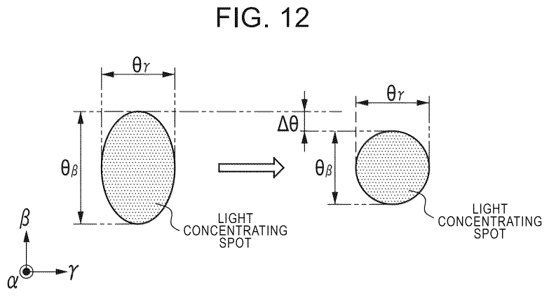

FIG. 11 shows a focal length Fc of a convex cylindrical surface 92b. As shown in FIG. 12, the focal length Fc is preferably determined such that the difference between a beam divergence angle θ_{β} in the first direction β and a beam divergence angle θ_{γ} in the second direction γ of the pulse laser light PL is minimized.

Further, the focal length Fc is preferably determined so as to satisfy Expression (1) below, where h represents the length of the beam cross section in the first direction β of the pulse laser light PL being incident on the second lens 92.

$$0.3 mrad \leq h / Fc \leq 1.5 mrad \qquad ( 1 )$$

Here, h/Fc corresponds to an angle φ shown in FIG. 11. It is assumed that the focal length Fc is sufficiently longer than the length h. Here, mrad is a unit representing an angle.

A change amount Δθ of the beam divergence angle θ_{β} due to the effect of the convex cylindrical surface 92b is expressed by Expression (2) below.

$$Δ θ = h / Fc \qquad ( 2 )$$

The first lens 91 and the second lens 92 are arranged on the optical path of the pulse laser light PL such that the flat surface 91b and the convex cylindrical surface 92b face each other. The pulse laser light PL output from the first OPS 50 is focused on the optical path of the pulse laser light PL between the first lens 91 and the second lens 92. The optical path length between the first lens 91 and the second lens 92 is equal to the sum of the focal length of the first lens 91 and the focal length of the convex spherical surface 92a of the second lens 92.

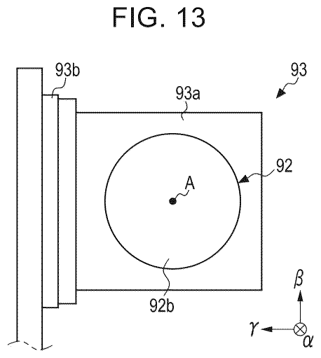

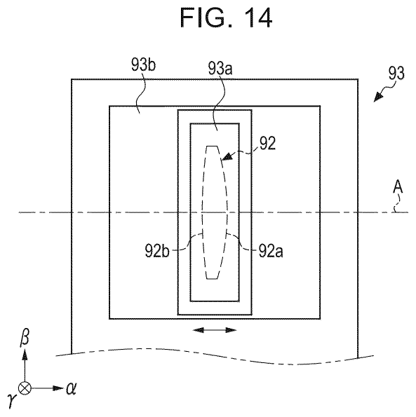

FIGS. 13 and 14 show the configuration of the optical path length changing mechanism 93. FIG. 13 is a view of the optical path length changing mechanism 93 viewed from the optical axis direction α. FIG. 14 is a view of the optical path length changing mechanism 93 viewed from the second direction γ.

The optical path length changing mechanism 93 includes a lens holder 93a and a linear stage 93b. The lens holder 93a holds the second lens 92 so that the optical axis A passes through the center of the second lens 92. The linear stage 93b holds the lens holder 93a so as to be movable along the optical axis direction α. The linear stage 93b changes the optical path length between the first lens 91 and the second lens 92 by moving the second lens 92 along the optical axis direction α based on the control of the laser processor 80.

### 3.2 Operation

Operation of the laser device 2 according to the present embodiment is similar to that of the comparative example. In the present embodiment, it is possible to perform adjustment operation by the optical path length changing mechanism 93 before operating the laser device 2.

In the adjustment operation, first, the laser processor 80 controls the optical path length changing mechanism 93 to position the second lens 92 at an initial position where the optical path length between the first lens 91 and the second lens 92 is equal to the sum of the focal length of the first lens 91 and the focal length of the convex spherical surface 92a of the second lens 92.

When the laser device 2 is operated in this state, the pulse laser light PL incident on the first lens 91 is concentrated behind the first lens 91 and then is incident on the second lens 92. The pulse laser light PL incident on the second lens 92 has the beam divergence angle θ_{β} in the first direction β changed by the effect of the convex cylindrical surface 92b.

The laser processor 80 controls the optical path length changing mechanism 93 to move the second lens 92 so that the beam divergence angle θ_{β} in the first direction β is minimized. For example, the beam divergence angle θ_{β} in the first direction β is measured using the two-dimensional image sensor 101 described above. As described above, since the focal length Fc of the convex cylindrical surface 92b is determined such that the difference between the beam divergence angle θ_{β} in the first direction β and the beam divergence angle θ_{γ} in the second direction γ becomes small, the beam divergence angle θ_{γ} in the second direction γ is also minimized by minimizing the beam divergence angle θ_{β} in the first direction β.

### 3.3 Effect

In the present embodiment, the relay lens including the first lens 91 and the second lens 92 is provided in the laser device 2, and since the second lens 92 has a shorter focal length in the longitudinal direction of the beam cross section than in the transverse direction thereof, it is possible to reduce the beam divergence angle in both the longitudinal direction and the transverse direction of the beam cross section. As a result, energy loss due to vignetting or the like in the exposure apparatus 200 is suppressed.

Further, in the present embodiment, since the beam divergence angle is adjusted by the two lenses being the first lens 91 and the second lens 92, it is possible to perform adjustment with high accuracy while suppressing loss of light amount due to transmission.

Here, it is also possible to arrange the second lens 92 upstream of the first lens 91, but it is preferable to arrange the second lens 92 downstream of the first lens 91. This is because it is more preferable to adjust the beam divergence angle on the downstream side than on the upstream side.

### 4. Second Embodiment

The laser device 2 according to a second embodiment of the present disclosure will be described.

### 4.1 Configuration

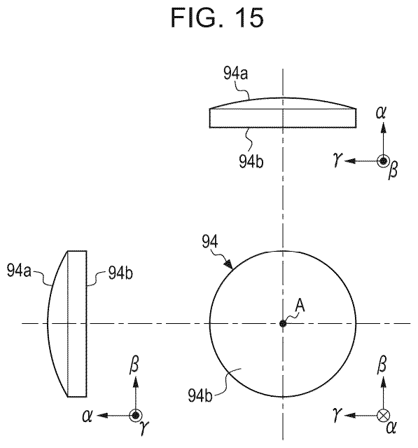

The laser device 2 according to the present embodiment has a similar configuration to the laser device 2 according to the first embodiment except that a second lens 94 shown in FIG. 15 is used instead of the second lens 92.

FIG. 15 shows the configuration of the second lens 94 according to the second embodiment. The second lens 94 is a toric lens having a toric surface 94a and a flat surface 94b opposed to each other. The toric surface 94a has a first curvature about an axis parallel to the first direction β and a second curvature about an axis parallel to the second direction γ, the second curvature being smaller than the first curvature. That is, in the toric surface 94a, the first curvature for concentrating the pulse laser light PL in the first direction β is larger than the second curvature for concentrating the pulse laser light PL in the second direction γ. At the position where the second lens 94 is arranged, the optical axis direction α corresponds to the Z-axis direction, the first direction β corresponds to the V-axis direction, and the second direction γ corresponds to the H-axis direction.

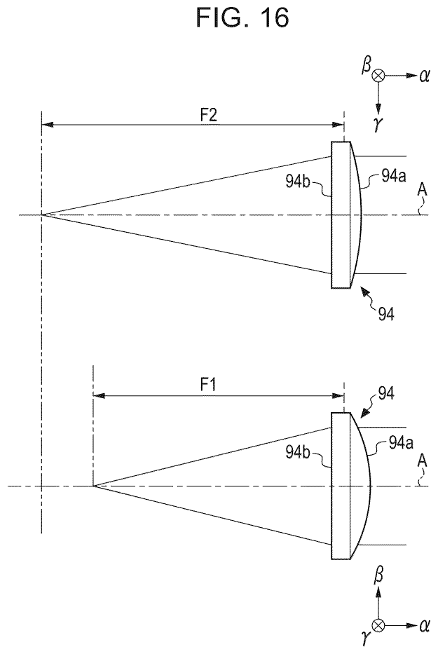

FIG. 16 shows a focal length F1 due to the first curvature of the second lens 94 and a focal length F2 due to the second curvature. The focal length F1 is shorter than the focal length F2. It is preferable that the focal length F2 is the same as the focal length of the convex spherical surface 91a of the first lens 91, and is in the range of 500 mm to 1000 mm both inclusive.

As shown in FIG. 12, the focal length F1 is preferably determined such that the difference between the beam divergence angle θ_{β} in the first direction β and the beam divergence angle θ_{γ} in the second direction γ of the pulse laser light PL is minimized.

Further, the focal length F1 may be determined so as to satisfy Expression (3) below, where h represents the length of the beam cross section in the first direction β of the pulse laser light PL being incident on the second lens 94.

$$0.3 mrad \leq ( h / F 1 - h / F 2 ) \leq 1.5 mrad \qquad ( 3 )$$

Similarly to the first embodiment, the second lens 94 is held by the optical path length changing mechanism 93 so as to be movable along the optical path of the pulse laser light PL.

### 4.2 Operation

Operation of the laser device 2 according to the present embodiment is similar to that of the comparative example. In the present embodiment, it is possible to perform adjustment operation by the optical path length changing mechanism 93 before operating the laser device 2.

In the adjustment operation, first, the laser processor 80 controls the optical path length changing mechanism 93 to position the second lens 94 at an initial position where the optical path length between the first lens 91 and the second lens 94 is equal to the sum of the focal length of the first lens 91 and the focal length F2 due to the second curvature of the second lens 94.

When the laser device 2 is operated in this state, the pulse laser light PL incident on the first lens 91 is concentrated behind the first lens 91 and then is incident on the second lens 94. The pulse laser light PL incident on the second lens 94 has the beam divergence angle θ_{β} in the first direction β and the beam divergence angle θ_{γ} in the second direction γ changed by the effect of the first curvature and the second curvature of the toric surface 94a.

The laser processor 80 controls the optical path length changing mechanism 93 to move the second lens 94 so that the beam divergence angle θ_{β} in the first direction β is minimized. As described above, since the focal length F1 due to the first curvature of the toric surface 94a is determined such that the difference between the beam divergence angle θ_{β} in the first direction β and the beam divergence angle θ_{γ} in the second direction γ becomes small, the beam divergence angle θ_{γ} in the second direction γ is also minimized by minimizing the beam divergence angle θ_{β} in the first direction β.

### 4.3 Effect

In the present embodiment, the relay lens including the first lens 91 and the second lens 94 is provided in the laser device 2, and since the second lens 94 includes the toric surface 94a in which the first curvature for concentrating the pulse laser light PL in the longitudinal direction of the beam cross section is larger than the second curvature for concentrating the pulse laser light PL in the transverse direction thereof, it is possible to reduce the beam divergence angle in both the longitudinal direction and the transverse direction of the beam cross section. As a result, energy loss due to vignetting or the like in the exposure apparatus 200 is suppressed.

In the present embodiment as well, since the beam divergence angle is adjusted by the two lenses being the first lens 91 and the second lens 94, it is possible to perform adjustment with high accuracy while suppressing loss of light amount due to transmission.

Further, it is also possible to arrange the second lens 94 upstream of the first lens 91, but it is preferable to arrange the second lens 94 downstream of the first lens 91. This is because it is more preferable to adjust the beam divergence angle on the downstream side than on the upstream side.

### 5. Modification

Various modifications of the embodiments will be described below.

In the above embodiments, the power oscillator 30 as an amplifier is provided between the master oscillator 10 and the first OPS 50 in the laser device 2, but the power oscillator 30 is not essential and can be omitted depending on the application of the device.

Further, in the above embodiments, the relay lens is arranged between the first OPS 50 and the second OPS 60, but may be arranged downstream of the second OPS 60.

Further, in the above embodiments, two optical pulse stretchers being the first OPS 50 and the second OPS 60 are provided in the laser device 2, but at least one optical pulse stretcher may be provided. In this case, the relay lens is preferably arranged downstream of the optical pulse stretcher.

### 6. Electronic Device Manufacturing Method

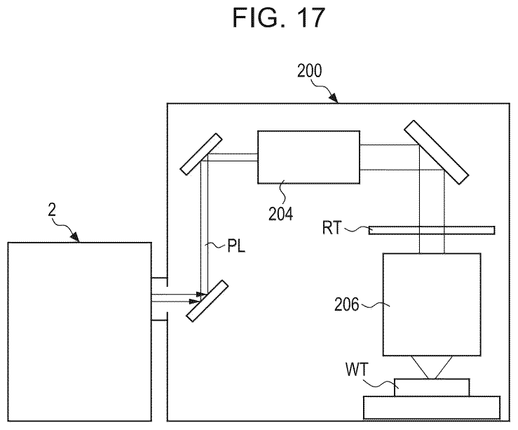

FIG. 17 schematically shows a configuration example of the exposure apparatus 200. The exposure apparatus 200 includes an illumination optical system 204 and a projection optical system 206. For example, the illumination optical system 204 illuminates a reticle pattern of a reticle (not shown) arranged on a reticle stage RT with the pulse laser light PL incident from the laser device 2. The projection optical system 206 causes the pulse laser light PL transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 200 synchronously translates the reticle stage RT and the workpiece table WT to expose the workpiece to the pulse laser light PL reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure.

Processors such as the laser processor 80 and the exposure control processor 210 may be physically configured as hardware to execute various processes included in the present disclosure. For example, the processor may be a computer including a memory that stores a control program defining the various processes and a processing device that executes the control program. The control program may be stored in one memory, or may be stored separately in a plurality of memories at physically separate locations, and the various processes may be defined by the control program as an aggregation thereof. The processing device may be a general-purpose processing device such as a central processing unit (CPU) or a special-purpose processing device such as a graphics processing unit (GPU).

Alternatively, the processor may be programmed as software to execute the various processes included in the present disclosure. For example, the processor may have a function of executing various processes implemented in a dedicated device such as an application specific integrated circuit (ASIC) or a programmable device such as a field programmable gate array (FPGA).

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. A laser device comprising:
a discharge-excitation-type laser oscillator configured to output pulse laser light in an ultraviolet wavelength range;
a first optical pulse stretcher including a beam splitter and a plurality of concave mirrors and configured to extend a pulse width of the pulse laser light; and
a relay lens including a first lens and a second lens arranged on an optical path of the pulse laser light with the pulse width extended,
the first lens being a spherical plano-convex lens, and
the second lens having a focal length in a longitudinal direction of a beam cross section of the pulse laser light shorter than a focal length in a transverse direction thereof.

2. The laser device according to claim 1,
wherein the second lens has a convex spherical surface and a convex cylindrical surface opposed to each other, and
the convex cylindrical surface concentrates the pulse laser light in the longitudinal direction.

3. The laser device according to claim 2,
wherein a relationship of 0.3 mrad≤h/Fc≤1.5 mrad is satisfied, where h represents a length of the beam cross section in the longitudinal direction and Fc represents a focal length of the convex cylindrical surface.

4. The laser device according to claim 2,
wherein a focal length of the convex spherical surface is in a range of 500 mm to 1000 mm both inclusive.

5. The laser device according to claim 2,
wherein the focal length of the second lens in the transverse direction is the same as a focal length of the first lens.

6. The laser device according to claim 1, wherein the second lens is arranged on the optical path downstream of the first lens.

7. The laser device according to claim 1,
wherein a focal length of the first lens is in a range of 500 mm to 1000 mm both inclusive.

8. The laser device according to claim 1, further comprising:
an optical path length changing mechanism configured to change an optical path length between the first lens and the second lens; and
a processor configured to control the optical path length changing mechanism.

9. The laser device according to claim 8,
wherein the processor changes the optical path length so that a beam divergence angle of the pulse laser light in the longitudinal direction becomes small.

10. The laser device according to claim 8,
wherein the second lens is arranged on the optical path downstream of the first lens, and the optical path length changing mechanism changes the optical path length by moving the second lens.

11. The laser device according to claim 1,
further comprising, between the laser oscillator and the first optical pulse stretcher, an amplifier configured to amplify the pulse laser light.

12. The laser device according to claim 1, wherein the second lens is a toric lens having a toric surface.

13. The laser device according to claim 12,
wherein the toric surface has a first curvature for concentrating the pulse laser light in the longitudinal direction and a second curvature for concentrating the pulse laser light in the transverse direction, and
the second curvature is smaller than the first curvature.

14. The laser device according to claim 13,
wherein a relationship of 0.3 mrad≤(h/F1−h/F2)≤1.5 mrad is satisfied, where h represents a length of the beam cross section in the longitudinal direction, F1 represents a focal length due to the first curvature, and F2 represents a focal length due to the second curvature.

15. The laser device according to claim 13,
wherein a focal length due to the second curvature is in a range of 500 mm to 1000 mm both inclusive.

16. The laser device according to claim 1,
further comprising a second optical pulse stretcher arranged on the optical path downstream of the first optical pulse stretcher,
wherein an optical path length of the first optical pulse stretcher is longer than an optical path length of the second optical pulse stretcher.

17. The laser device according to claim 16,
wherein the first lens and the second lens are arranged on the optical path between the first optical pulse stretcher and the second optical pulse stretcher.

18. The laser device according to claim 16,
wherein the first lens is arranged in a housing that accommodates the first optical pulse stretcher, and
the second lens is arranged on the optical path outside the housing and upstream of the second optical pulse stretcher.

19. The laser device according to claim 16,
wherein the first lens and the second lens are arranged on the optical path downstream of the second optical pulse stretcher.

20. An electronic device manufacturing method, comprising:
outputting pulse laser light from a laser device to an exposure apparatus; and
exposing a photosensitive substrate to the pulse laser light in the exposure apparatus to manufacture an electronic device,
the laser device including:
a discharge-excitation-type laser oscillator configured to output the pulse laser light in an ultraviolet wavelength range;
a first optical pulse stretcher including a beam splitter and a plurality of concave mirrors and configured to extend a pulse width of the pulse laser light; and
a relay lens including a first lens and a second lens arranged on an optical path of the pulse laser light with the pulse width extended,
the first lens being a spherical plano-convex lens, and
the second lens having a focal length in a longitudinal direction of a beam cross section of the pulse laser light shorter than a focal length in a transverse direction thereof.
